(19) United States
(12) Patent Application Publication
(10) Pub. No.: US 2015/0146846 A1
(43) Pub. Date: May 28, 2015

(54) METHOD AND APPARATUS FOR ELIMINATING RESIDUAL CHARGES IN A FLAT-PANEL X-RAY DETECTOR

(71) Applicant: Industrial Technology Research Institute, Hsinchu (TW)

(72) Inventor: Shiow-Harn LEE, Hsinchu County (TW)

(73) Assignee: Industrial Technology Research Institute, Hsinchu (TW)

(21) Appl. No.: 14/201,366

(22) Filed: Mar. 7, 2014

(30) Foreign Application Priority Data
Nov. 22, 2013 (TW) 102142625

(51) Int. Cl. H04N 5/32

(52) U.S. Cl. CPC H04N 5/32
USPC 378/31

(57) ABSTRACT

A method and an apparatus for eliminating residual charges in a flat-panel x-ray detector are provided. The apparatus includes a flat-panel x-ray detector, a first bias voltage source and a second bias voltage source. The flat-panel x-ray detector includes a photoconductor layer and an electrode layer disposed on the photoconductor layer. The electrode layer converts x-rays to positive and negative charges. The first bias voltage source generates a first bias voltage applied to the photoconductor layer to form a first electric field. The second bias voltage source generates a second bias voltage applied to the photoconductor layer to form a second electric field. The first and second bias voltages are polar opposites. The positive and negative charges respectively at two opposite surfaces of the photoconductor layer in the first electric field are driven from one surface to the other one to be neutralized in the second electric field.

### CROSS-REFERENCE TO RELATED APPLICATIONS

This non-provisional application claims priority under 35 U.S.C. §119(a) on Patent Application No(s). 102142625 filed in Taiwan, R.O.C. on Nov. 12, 2013, the entire contents of which are hereby incorporated by reference.

### TECHNICAL FIELD

The disclosure relates to a method and an apparatus for eliminating residual charges in a flat-panel x-ray detector.

### BACKGROUND

FIG. 1 is a schematic view illustrating a detection theory of a direct digital radiography (DDR) flat-panel detector. Generally, a flat-panel x-ray detector 100 (or called a planer x-ray detector) for x-ray DDR includes a photoconductor layer 101, an electrode layer 102 and a plurality of pixel electrodes 103. The photoconductor layer 101 converts x-rays 200 to many electron-hole pairs spread in the photoconductor layer 101. As shown in FIG. 1, electrons are negative charges ⊖, and electron holes are positive charges ⊕. When the electrode layer 102 is supplied with a bias voltage 110, negative charges ⊖ will go up to the electrode layer 102, and positive charges ⊕ will go down to the pixel electrodes 103. Herein, the pixel electrodes 103 can couple with capacitors 105 in a storage layer 104, and charges at the pixel electrodes 103 can be transferred to the capacitors 105 and then be acquired from the capacitors 105 via thin-film transistors (TFT) 106 in the storage layer 104. Therefore, images generated by projecting x-rays on objects can be converted to electric signals for pixels.

However, it needs several thousands seconds to spontaneously eliminate charges generated by converting x-rays in the photoconductor layer 101. If there are residual charges in the photoconductor layer 101 and meanwhile the photoconductor layer 101 is irradiated with x-rays again, these residual charges and new charges will be acquired by the pixel electrodes 103 simultaneously to produce a new x-ray image with a residual image caused by these residual charges. This situation is called Ghosting, as shown in FIG. 2A and FIG. 2B.

Accordingly, some solutions to speed up the elimination of charges in the photoconductor layer 101 are proposed, for example, to use a photoconductor layer with a tunable discharge coefficient. However, to use a photoconductor layer with a tunable discharge coefficient may increase dark currents and then cause some errors on the acquiring of charges for pixels. On the other hand, some solutions to eliminate residual images from ghosting images are also proposed, for example, to calibrate these ghosting images according to the area and location of each residual image calculated by a complicated algorithm. However, the circuit design of eliminating residual images is more complicated and costs a lot. Furthermore, to use a photoconductor layer with a tunable discharge coefficient and to calibrate ghosting images have to take more than 20 seconds, and since it is necessary for the video photography to capture a specific number of images per second, the DDR may not be performed on the video photography.

### SUMMARY

According to one or more embodiments, the disclosure provides a method of eliminating residual charges in a flat-panel x-ray detector. Firstly, a first bias voltage is applied between a first surface and a second surface of a photoconductor layer to produce a first electric field, there are positive charges and negative charges generated by converting x-rays in the photoconductor layer, and the first electric field separates the positive charges from the negative charges in the photoconductor layer, makes the positive charges gather at one of the first surface and the second surface, and makes the negative charges gather at the other one of the first surface and the second surface. Then, a second bias voltage is applied between the first surface and the second surface of the photoconductor layer to produce a second electric field, the first bias voltage and the second bias voltage are polar opposites, and the second electric field moves the positive charges to the other one of the first surface and the second surface, and moves the negative charges to the one of the first surface and the second surface. Therefore, the moved positive charges and the moved negative charges are neutralized and then eliminated.

According to one or more embodiments, the disclosure also provides an apparatus of eliminating residual charges in a flat-panel x-ray detector, and the apparatus of eliminating residual charges includes the flat-panel x-ray detector, a first bias voltage source and a second bias voltage source. The flat-panel x-ray detector includes a photoconductor layer and an electrode layer. The photoconductor layer has a first surface and a second surface and converts x-rays to positive charges and negative charges, and the electrode layer is located on the first surface of the photoconductor layer. The first bias voltage source couples with the electrode layer and generates a first bias voltage which is applied between the first surface and the second surface of the photoconductor layer to produce a first electric field. Through the first electric field, the positive charges are separated from the negative charges in the photoconductor layer, the positive charges are gathered at one of the first surface and the second surface, and the negative charges are gathered at the other one of the first surface and the second surface. The second bias voltage source couples with the electrode layer and generates a second bias voltage which is applied between the first surface and the second surface of the photoconductor layer to produce a second electric field, and the first bias voltage and the second bias voltage are polar opposites. Through the second electric field, the positive charges are moved to the other one of the first surface and the second surface, and the negative charges are moved to the one of the first surface and the second surface. Therefore, the moved positive charges and the moved negative charges are neutralized and then eliminated.

According to one or more embodiments, the disclosure also provides an apparatus of eliminating residual charges in a flat-panel x-ray detector, and the apparatus of eliminating residual charges includes the flat-panel x-ray detector. The flat-panel x-ray detector includes a photoconductor layer, an electrode layer, and at least one power supply. The photoconductor layer converts x-rays to positive charges and negative charges. The electrode layer is located on the first surface of the photoconductor layer. The at least one power supply couples with the electrode layer and generates a first bias voltage and a second bias voltage. The first bias voltage is applied between the first surface and the second surface of the photoconductor layer to produce a first electric field, and the second bias voltage is applied between the first surface and the second surface of the photoconductor layer to produce a second electric field. The first bias voltage and the second bias voltage are polar opposites. Through the first electric field, the positive charges are separated from the negative charges, the positive charges are gathered at one of the first surface and the second surface, and the negative charges are gathered at the other one of the first surface and the second surface. Through the second electric field, the positive charges are moved to the other one of the first surface and the second surface, and the negative charges are moved to the one of the first surface and the second surface. Therefore, the moved positive charges and the moved negative charges are neutralized and then eliminated.

### BRIEF DESCRIPTION OF THE DRAWINGS

The present disclosure will become more fully understood from the detailed description given herein below for illustration only and thus does not limit the present disclosure, wherein:

FIG. 1 is a schematic view illustrating a detection theory of a direct digital radiography (DDR) flat-panel detector;

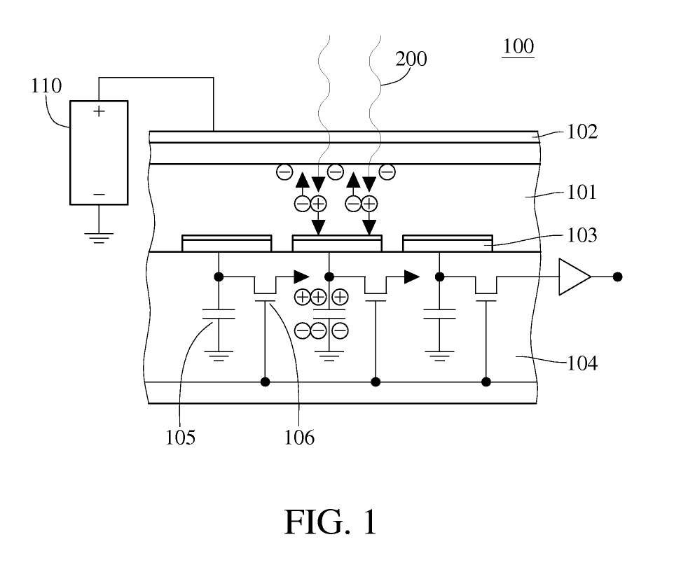

FIG. 2A and FIG. 2B are schematic views of x-ray photographs with residual images;

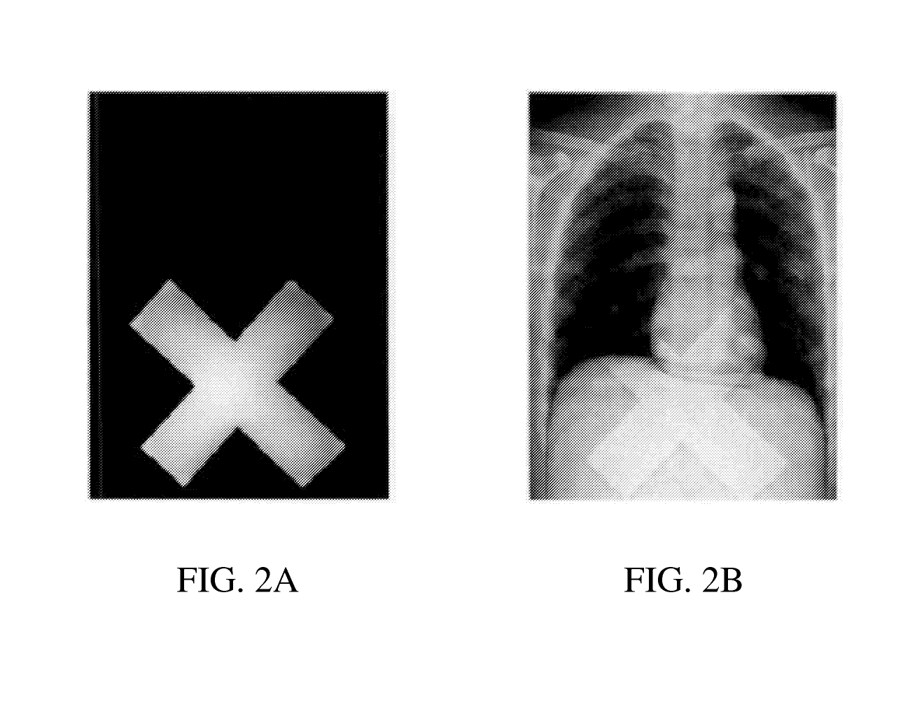

FIG. 3 is a schematic view of an apparatus of eliminating residual charges in an embodiment of the disclosure;

FIG. 4 is an operational sequence diagram in the disclosure; and

FIG. 5 is a schematic view of an apparatus of eliminating residual charges in an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

In the following description, the term “couple” or “connect” may indicate to directly or indirectly couple or connect one component with another.

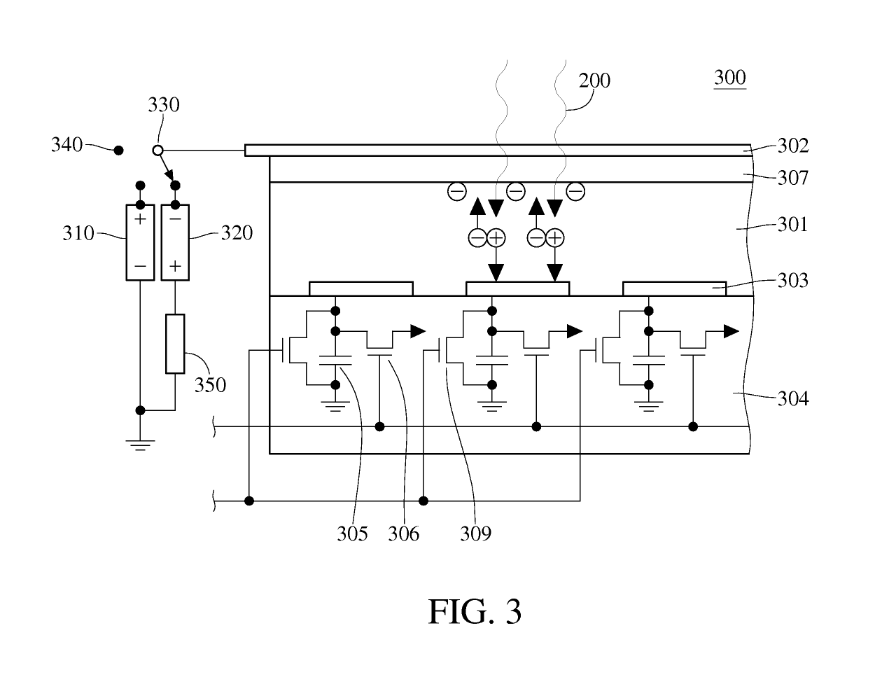

FIG. 3 is a schematic view of an apparatus of eliminating residual charges in an embodiment of the disclosure. The disclosure is adapted to eliminate residual charges in a flat-panel x-ray detector 300 (or called as a planer x-ray detector) for direct digital radiography (DDR). The flat-panel x-ray detector 300 includes a photoconductor layer 301, an electrode layer 302, a plurality of pixel electrodes 303 and a storage layer 304. The photoconductor layer 301 has a first surface and a second surface and converts x-rays 200 to positive charges [symbol] and negative charges ⊖. For example, the material of the photoconductor layer 301 includes amorphous selenium (a-Se). The electrode layer 302 is formed on the first surface. In one of the embodiments, there is a dielectric layer 307 with a tunable resistance value formed between the electrode layer 302 and the first surface of the photoconductor layer 301, so that an insulation layer capable of suppressing dark currents is formed between the electrode layer 302 and the photoconductor layer 301. For example, the material of the dielectric layer 307 includes polyurethane (or linear segmented polyurethane) or ethylene glycol.

The storage layer 304 is formed on the second surface of the photoconductor layer 301. For example, the storage layer 304 is a glass substrate. The pixel electrodes 303 are spread between the storage layer 304 and the second surface of the photoconductor layer 301. The pixel electrode 303 collects and receives positive charges or negative charges gathered at the second surface of the photoconductor layer 301. In one of the embodiments, there is an insulation layer (not shown) formed between the pixel electrodes 303 and the second surface of the photoconductor layer 301 and formed between the second surface and the exposed storage layer 304. In the disclosure, the storage layer 304 includes a plurality of charges storing components and a plurality of charges output components. Each charge storing component couples with one pixel electrode 303 and stores the positive charges or the negative charges received by the pixel electrode 303. For example, the charges storing component is a capacitor 305 coupled with one pixel electrode 303. For example, the charge output component is a thin-film transistor 306, where the source end (S) of the thin-film transistor 306 couples with one pixel electrode 303, the drain end (D) of the thin-film transistor 306 couples to an output end, and the gate end (G) of the thin-film transistor 306 is controlled by a control signal. Therefore, charges stored in the capacitor 305 will be outputted as electric signals.

The apparatus of eliminating residual charges includes a first bias voltage source 310, a second bias voltage source 320 and a switch device 330, and the first bias voltage source 310 and the second bias voltage source 320 couple with the electrode layer 302 through a switch device 330. For example, the switch device 330 is a single pole three throw (1P3T). switch for sequentially conducting the first bias voltage source 310, the second bias voltage source 320 and a floating end 340 to the electrode layer 302. For example, the switch device 330 is a single pole double throw (SPDT) switch (not shown) coupling the first bias voltage source 310 or the second bias voltage source 320 to the electrode layer 302.

The first bias voltage source 310 generates a first bias voltage and applies the first bias voltage between the first and second surfaces of the photoconductor layer 301 through the electrode layer 302 to produce a first electric field between the first and second surfaces. The first electric field separates the positive charges from the negative charges in the photoconductor layer 101, makes the positive charges gather at one of the first and second surfaces, and makes the negative charges gather at the other one of the first and second surfaces. In an example, when the first bias voltage is a positive voltage, the first electric field makes the negative charges ⊖ gather at the first surface, and makes the positive charges [symbol] gather at the second surface. In another example, when the first bias voltage is a negative voltage, the first electric field makes the positive charges [symbol] gather at the first surface, and makes the negative charges ⊖ gather at the second surface.

The second bias voltage source 320 generates a second bias voltage whose polarity is different from the polarity of the first bias voltage. For example, while the first bias voltage is a positive voltage, the second bias voltage is a negative voltage. For example, while the first bias voltage is a negative voltage, the second bias voltage is a positive voltage. For example, the second bias voltage is a momentary pulse voltage. The current related to the second bias voltage is smaller than the current related to the first bias voltage. For example, a circuit for the second bias voltage source 320 is disposed with a current limit resistor 350, to prevent the thin-film transistor 306 in the storage layer 304 from be damaged by surge current caused by the momentary pulse voltage.

As the same as the first bias voltage, the second bias voltage is applied between the first and second surfaces of the photoconductor layer 301 through the electrode layer 302 to produce a second electric field between the first and second surfaces. Since the polarity of the second bias voltage is different from the polarity of the first bias voltage, the first electric field and the second electric field are polar opposites. The second electric field may move the positive charges or the negative charges gathered at the first surface to the second surface, and move the positive charges or the negative charges gathered at the second surface to the first surface. In other words, the positive charges gathered at the one of the first and second surfaces are shifted to the other one of the first and second surfaces, and the negative charges gathered at the other one of the first and second surfaces are shifted to the one of the first and second surfaces. For example, when the first bias voltage is positive and the second bias voltage is negative, the negative charges ⊖ gathered at the first surface will be moved to the second surface, and the positive charges [symbol] gathered at the second surface will be moved to the first surface. During the move of the positive charges and the negative charges, the positive charges and the negative charges are neutralized to eliminate charges in the photoconductor layer 301. Alternately, when the first bias voltage is negative and the second bias voltage is positive, the positive charges [symbol] gathered at the first surface will be moved to the second surface, and the negative charges ⊖ gathered at the second surface will be moved to the first surface. During the move of the positive charges and the negative charges, the positive charges and the negative charges are neutralized to eliminate charges in the photoconductor layer 301.

In one embodiment, the second bias voltage source 320 may further generate a third bias voltage (not shown in figures), e.g. a momentary pulse voltage, which is applied between the first and second surfaces of the photoconductor layer 301 through the electrode layer 302 to produce a third electric field. The second bias voltage and the third bias voltage are polar opposites, so the second electric field and the third electric field are polar opposites. In this way, if there are some residual charges in the photoconductor layer 301, they will be moved from one surface to the other and be neutralized and eliminated during the move. Therefore, the second bias voltage source 320 may alternately and continuously generates the second bias voltage and the third bias voltage until the charges in the photoconductor layer 301 are eliminated completely.

In one embodiment, each pixel electrode 303 is coupled to a ground terminal through a switch 309, e.g. a thin-film transistor. After the second bias voltage is applied, the switch 309 will be turned on, and the pixel electrode 303 will be grounded. Herein, the charges not neutralized in the photoconductor layer 301 will be released to the ground terminal through the pixel electrode 303 and then be eliminated.

In one embodiments, the thin-film transistor as the switch 309 may be replaced by the thin-film transistor 306 as the charge output component, where the drain end of the thin-film transistor 306 couples to the ground terminal instead of the output end.

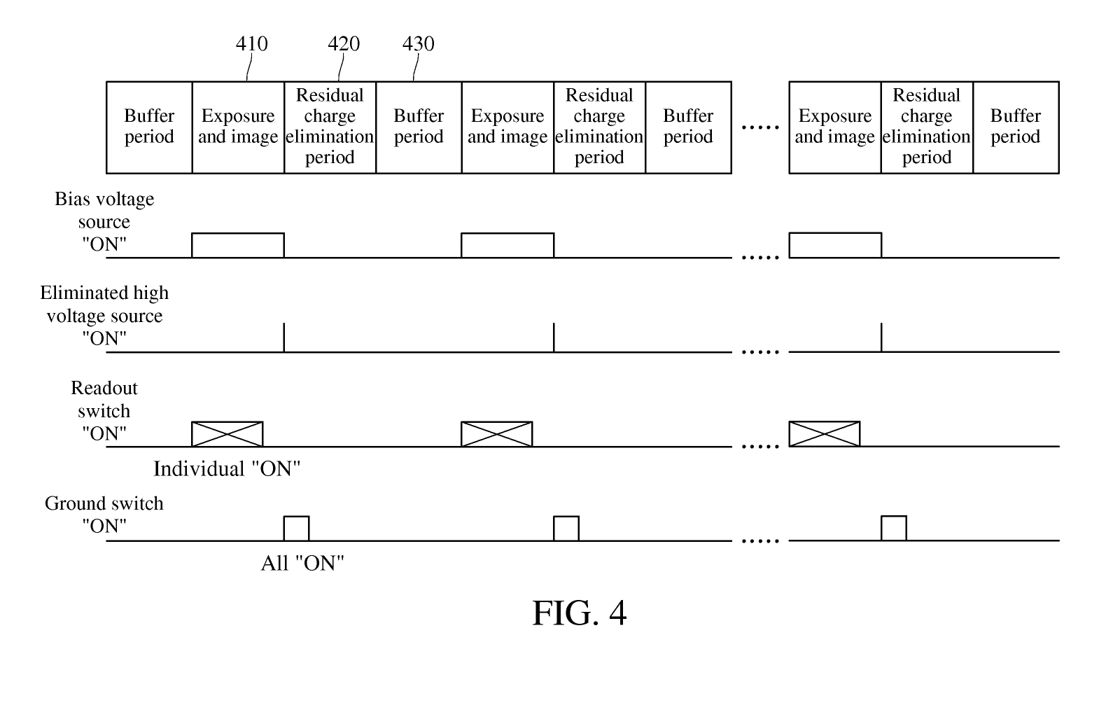

The detailed operation of the disclosure is described as follows. Referring to FIG. 3 and FIG. 4, during an exposure and image-capturing period 410, the switch device 330 is firstly selects the first bias voltage source 310 and couples the first bias voltage source 310 with the electrode layer 302, and then the first bias voltage is applied between the first and second surfaces of the photoconductor layer 301 to produce the first electric field between the first and second surfaces. When x-rays are projected on the flat-panel x-ray detector 300, the photoconductor layer 301 converts the x-rays to positive charges and negative charges, and the positive charges are separated from the negative charges by the first electric field in the photoconductor layer 301. Assume the first bias voltage is positive. The negative charges ⊖ will gather at the first surface of the photoconductor layer 301 (i.e. the surface close to the electrode layer 302), and the positive charges [symbol] will gather at the second surface (i.e. the surface close to the pixel electrode 303). Alternately, assume the first bias voltage is negative. The positive charges [symbol] will gather at the first surface, and the negative charges ⊖ will gather at the second surface. Since each pixel electrode 303 in the storage layer 304 collects and receives the charges at the second surface, and stores them in the charge storing component (e.g. the capacitor 305). Subsequently, the gate end of each charge output component (e.g. the thin-film transistor 306) is turned on according to an acquiring signal, and then the charges stored in the charge storing component (e.g. the capacitor 305) are outputted as electric signals. In this way, x-ray images can be converted to a plurality of electric signals for pixels.

Following the exposure and image-capturing period 410, in a residual charge elimination period 420, the switch device 330 selects the second bias voltage source 320 instead of the first bias voltage source 310 and couples the second bias voltage source 320 to the electrode layer 302, and then the second bias voltage is applied between the first and second surfaces of the photoconductor layer 301 to produce the second electric field. Because the first bias voltage and the second bias voltage are polar opposites, the second electric field moves the positive charges or the negative charges, gathered at the first surface, to the second surface and moves the positive charges or the negative charges, gathered at the second surface, to the first surface. During the move, the positive charges and the negative charges are neutralized by each other and then eliminated. Assume the first bias voltage is positive, and the second bias voltage is negative. The second electric field moves the negative charges ⊖ to the second surface, and moves the positive charges [symbol] to the first surface. Alternately, assume the first bias voltage is negative, and second bias voltage is negative. The second electric field moves the positive charges [symbol] to the second surface, and moves the negative charges ⊖ to the first surface.

In one embodiment, the duration of applying the first bias voltage includes the entire exposure and image-capturing period 410, the second bias voltage is a momentary pulse voltage, and the duration of applying the second bias voltage is a short period at the beginning of the residual charge elimination period 420. In one other embodiment, in order to utterly eliminate residual charges in the photoconductor layer 301, the second bias voltage generated by the second bias voltage source 320 is inverted to become a third bias voltage during the residual charge elimination period 420. For example, the switch device 330 switches from the second bias voltage source 320 to the first bias voltage source 310 and couples the first bias voltage source 310 to the electrode layer 302 for a while to generate a momentary pulse voltage as the third bias voltage. The third bias voltage is applied between the first and second surfaces to produce a third electric field which moves charges in the photoconductor layer 301 from one surface to the other one, and the charges will be neutralized by each other and then eliminated. The second bias voltage and the third bias voltage may be alternately applied at least one time.

In one embodiment, the exposure and image-capturing period 410 directly follows the residual charge elimination period 420, and the relative operation during the exposure and image-capturing period 410 and the relative operation during the residual charge elimination period 420 are alternatively many times to capture videos. In another embodiment, a buffer period 430 follows the residual charge elimination period 420 and is followed by the exposure and image-capturing period 410, and the relative operation during the exposure and image-capturing period 410, the relative operation during the residual charge elimination period 420, and the relative operation during the buffer period 430 are sequentially performed many times to capture videos.

In the embodiment including the switch 309 grounded, during the residual charge elimination period 420, the switch 309 is turned on according to a residual elimination signal to couple all of the pixel electrodes 303 to the ground terminal after the second bias voltage or the third bias voltage is applied to the photoconductor layer 301, and then residual charges in the photoconductor layer 301 will be conducted to the ground terminal and be eliminated from the photoconductor layer 301.

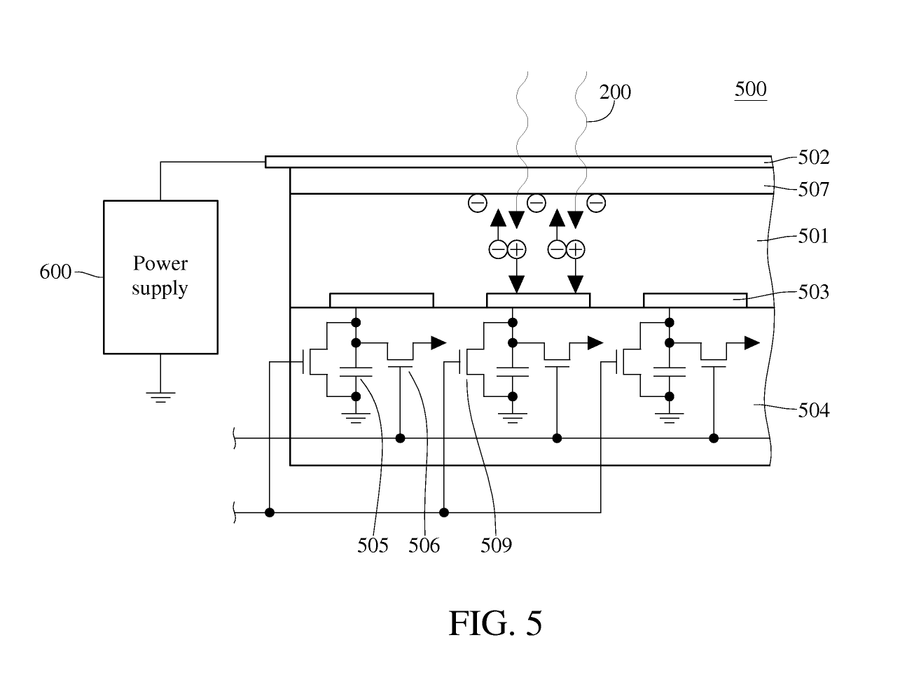

The disclosure also provides one or more embodiments of an apparatus for eliminating residual charges as shown in FIG. 4 and FIG. 5, and FIG. 5 is a schematic view of an apparatus of eliminating residual charges in an embodiment of the disclosure. The apparatus for eliminating residual charges in FIG. 5 includes a flat-panel x-ray detector 500 and a power supply 600. The flat-panel x-ray detector 500 includes a photoconductor layer 501, an electrode layer 502, a plurality of pixel electrodes 503 and a storage layer 504, which is the same as the flat-panel x-ray detector 300 in FIG. 3 and thus is not repeated hereinafter. The power supply 600 couples with the electrode layer 502 and is programmable to generate a first bias voltage during the exposure and image-capturing period 410 and generate a second bias voltage during the residual charge elimination period 420. The first bias voltage and the second bias voltage are polar opposites and are sequentially applied between the first and second surfaces of the photoconductor layer 501 to respectively produce a first electric field and a second electric field. The first electric field separates positive charges from negative charges in the photoconductor layer 501, makes the positive charges gather at one of the first and second surfaces, and makes the negative charges gather at the other one of the first and second surfaces. The second electric field moves the charges from one surface to the other one, and the moved positive charges and the moved negative charges will be neutralized by each other to be eliminated during the move.

In one of the embodiments, the power supply 600 is programmable to control the polarities of the first bias voltage and the second bias voltage, the output currents related to the first bias voltage and the second bias voltage, and the duration of applying bias voltage. For example, during the exposure and image-capturing period 410, and the power supply 600 may generate a positive voltage as the first bias voltage, the duration of applying the first bias voltage includes the entire exposure and image-capturing period 410. Herein, each pixel electrode 503 collects and receives charges at the second surface, and stores them in the charge storing component (e.g. the capacitor 505). Then, during the residual charge elimination period 420, the power supply 600 may generate a momentary pulse voltage as the second bias voltage, and the current related to the second bias voltage is smaller than the current related to the first bias voltage. Herein, the current related to the second bias voltage may not damage the charge output component (e.g. the thin-film transistor 506). In another one of the embodiments, the power supply 600 may generate a momentary pulse voltage as a third bias voltage during the residual charge elimination period 420, and the second bias voltage and the third bias voltage are polar opposites. The third bias voltage is applied between the first and second surfaces of the photoconductor layer 501 to produce a third electric field for moving the residual positive charges and the residual negative charges in the photoconductor layer 501 again during the residual charge elimination period 420, so that the residual positive charges and the residual negative charges are neutralized by each other and then eliminated during the move. Moreover, the power supply 600 may generate the second bias voltage and the third bias voltage many times to utterly eliminate all residual charges in the photoconductor layer 501.

What is claimed is:

1. A method of eliminating residual charges in a flat-panel x-ray detector, comprising:
applying a first bias voltage between a first surface and a second surface of a photoconductor layer in which there are positive charges and negative charges generated by converting x-rays, to produce a first electric field between the first surface and the second surface, wherein through the first electric field, the positive charges are separated from the negative charges and gathered at one of the first surface and the second surface, and the negative charges are gathered at the other one of the first surface and the second surface; and
applying a second bias voltage between the first surface and the second surface of the photoconductor layer to produce a second electric field between the first surface and the second surface, wherein the first bias voltage and the second bias voltage are polar opposites, and through the second electric field, the positive charges are moved to the other one of the first surface and the second surface and the negative charges are moved to the one of the first surface and the second surface, to neutralize and eliminate the moved positive charges and the moved negative charges.

2. The method of eliminating residual charges according to claim 1, wherein to apply the first bias voltage between the first surface and the second surface of the photoconductor layer is performed during an exposure and image-capturing period, to apply the second bias voltage between the first surface and the second surface is performed during a residual charge elimination period, and the exposure and image-capturing period and the residual charge elimination period are alternate.

3. The method of eliminating residual charges according to claim 2, wherein there is a buffer period between the residual charge elimination period, and the exposure and image-capturing period is after the buffer period.

4. The method of eliminating residual charges according to claim 2, wherein duration of applying the first bias voltage includes the exposure and image-capturing period.

5. The method of eliminating residual charges according to claim 2, wherein the second bias voltage is a momentary pulse voltage.

6. The method of eliminating residual charges according to claim 5, further comprising the following steps in the residual charge elimination period:
inverting the second bias voltage to generate a third bias voltage; and
applying the third bias voltage between the first surface and the second surface to produce a third electric field for moving the rest of the positive charges to the one of the first surface and the second surface or moving the rest of the negative charges to the other one of the first surface and the second surface to neutralize the positive charges and the negative charges.

7. The method of eliminating residual charges according to claim 1, wherein the first bias voltage is a positive voltage, the second bias voltage is a negative voltage, the first electric field makes the negative charges gather at the first surface and makes the positive charges gather at the second surface, and the second electric field moves the negative charges to the second surface and moves the positive charges to the first surface.

8. The method of eliminating residual charges according to claim 1, wherein the first bias voltage is a negative voltage, the second bias voltage is a positive voltage, the first electric field makes the positive charges gather at the first surface and makes the negative charges gather at the second surface, and the second electric field moves the positive charges to the second surface and moves the negative charges to the first surface.

9. The method of eliminating residual charges according to claim 1, wherein there is an electrode layer on the first surface of the photoconductor layer, and the first bias voltage and the second bias voltage are applied at the electrode layer.

10. The method of eliminating residual charges according to claim 9, wherein the first bias voltage and the second bias voltage are provided by a first bias voltage source and a second bias voltage source respectively, and the first bias voltage source or the second bias voltage source by the control is selected via a switch device to couple with the electrode layer.

11. The method of eliminating residual charges according to claim 10, wherein the second bias voltage source couples with a current limit resistor, and a current related to the second bias voltage is smaller than a current related to the first bias voltage.

12. The method of eliminating residual charges according to claim 9, wherein the first bias voltage and the second bias voltage are provided by a power supply coupled with the electrode layer, and the power supply controls the polarities of the first bias voltage and the second bias voltage, output currents related to the first bias voltage and the second bias voltage, and duration of applying the first bias voltage and the second bias voltage.

13. The method of eliminating residual charges according to claim 2, in the exposure and image-capturing period, further comprising the following steps after the first bias voltage is applied to the photoconductor layer:
coupling the positive charges or the negative charges at the second surface to a plurality of pixel electrodes to produce electric signals for a plurality of pixels.

14. The method of eliminating residual charges according to claim 13, wherein the pixel electrode is coupled with a charge storing component and a charge output component, the charge storing component is configured to store the positive charges or the negative charges received by the pixel electrode, and the charge output component is configured to acquire the positive charges or the negative charges stored in the charge storing component to produce electric signals for the pixels.

15. The method of eliminating residual charges according to claim 2, in the residual charge elimination period, further comprising the following steps after the second bias voltage is applied to the photoconductor layer:
coupling a plurality of pixel electrodes on the second surface of the photoconductor layer to a ground terminal to eliminating residual charges in the photoconductor layer.

16. The method of eliminating residual charges according to claim 14, wherein the pixel electrode is coupled to the ground terminal through a switch.

17. An apparatus of eliminating residual charges in a flat-panel x-ray detector, comprising:
the flat-panel x-ray detector comprising a photoconductor layer which has a first surface and a second surface and is configured to convert X-rays to positive charges and negative charges, and an electrode layer disposed on the first surface;
a first bias voltage source coupled with the electrode layer and configured to apply a first bias voltage between the first surface and the second surface to produce a first electric field which separates the positive charges from the negative charges, makes the positive charges gather at one of the first surface and the second surface, and makes the negative charges gather at the other one of the first surface and the second surface; and
a second bias voltage source coupled with the electrode layer and configured to apply a second bias voltage between the first surface and the second surface to produce a second electric field which moves the positive charges to the other one of the first surface and the second surface and moves the negative charges to the one of the first surface and the second surface to neutralize the positive charges and the negative charges, wherein the first bias voltage and the second bias voltage are polar opposites.

18. The apparatus of eliminating residual charges according to claim 16, wherein the material of the photoconductor layer comprises a-Se.

19. The apparatus of eliminating residual charges according to claim 16, wherein the flat-panel x-ray detector further comprises:
a dielectric layer located between the electrode layer and the first surface.

20. The apparatus of eliminating residual charges according to claim 19, wherein the material of the dielectric layer comprises linear segmented polyurethane or ethylene glycol.

21. The apparatus of eliminating residual charges according to claim 16, wherein the flat-panel x-ray detector further comprises:
a storage layer located on the second surface; and
a plurality of pixel electrodes distributed between the storage layer and the second surface, and configured to collect and receive the positive charges and the negative charges.

22. The apparatus of eliminating residual charges according to claim 21, wherein the storage layer is a glass substrate.

23. The apparatus of eliminating residual charges according to claim 21, wherein the flat-panel x-ray detector further comprises:
an insulation layer located between the pixel electrodes and the second surface and between the second surface and an exposed part of the storage layer.

24. The apparatus of eliminating residual charges according to claim 16, wherein the first bias voltage is a positive voltage, the second bias voltage is a negative voltage, the first electric field makes the negative charges gather at the first surface and makes the positive charges gather at the second surface, and the second electric field moves the negative charges to the second surface and moves the positive charges to the first surface.

25. The apparatus of eliminating residual charges according to claim 16, wherein the first bias voltage is a negative voltage, the second bias voltage is a positive voltage, the first electric field makes the positive charges gather at the first surface and makes the negative charges gather at the second surface, and the second electric field moves the positive charges to the second surface and moves the negative charges to the first surface.

26. The apparatus of eliminating residual charges according to claim 16, further comprising:
a switch device coupled with the first bias voltage source, the second bias voltage source and the electrode layer and configured to couple the first bias voltage source or the second bias voltage source to the electrode layer.

27. The apparatus of eliminating residual charges according to claim 16, wherein the second bias voltage is a momentary pulse voltage.

28. The apparatus of eliminating residual charges according to claim 27, wherein the second bias voltage source is further coupled with a current limit resistor through which a current related to the second bias voltage is smaller than a current related to the first bias voltage.

29. The apparatus of eliminating residual charges according to claim 28, wherein the second bias voltage source further generates a third bias voltage which is applied between the first surface and the second surface to produce a third electric field therebetween for moving the rest of the positive charges to the one of the first surface and the second surface and moving the rest of the negative charges to the other one of the first surface and the second surface to neutralize the positive charges and the negative charges, and the second bias voltage and the third bias voltage are polar opposites.

30. The apparatus of eliminating residual charges according to claim 29, wherein the second bias voltage source alternately generates the second bias voltage and the third bias voltage.

31. The apparatus of eliminating residual charges according to claim 21, wherein the storage layer further comprises:
a plurality of switches respectively coupled with the pixel electrodes and a ground terminal and configured to eliminate residual charges in the photoconductor layer.

32. The apparatus of eliminating residual charges according to claim 31, wherein the switch is a thin-film transistor.

33. The apparatus of eliminating residual charges according to claim 21, wherein the storage layer further comprises:
a plurality of charge storing components respectively coupled with the pixel electrodes and configured to store the positive charges or the negative charges received by the pixel electrodes; and
a plurality of charge output components respectively coupled with the charge storing components and configured to acquire the positive charges or the negative charges stored in the charge storing components.

34. The apparatus of eliminating residual charges according to claim 33, wherein the charge storing component is a capacitor, and the charge output component is a thin-film transistor.

35. An apparatus of eliminating residual charges in a flat-panel x-ray detector, comprising:
the flat-panel x-ray detector comprising:
a photoconductor layer configured to convert X-rays to positive charges and negative charges and having a first surface and a second surface;
an electrode layer located on the first surface; and
at least one power supply coupled with the electrode layer and configured to alternately generate a first bias voltage for being applied between the first surface and the second surface to produce a first electric field which separates the positive charges from the negative charges, makes the positive charges gather at one of the first surface and the second surface and makes the negative charges gather at the other one of the first surface and the second surface, and a second bias voltage for being applied between the first surface and the second surface to produce a second electric field which moves the positive charges to the other one of the first surface and the second surface and moves the negative charges to the one of the first surface and the second surface to neutralize the positive charges and the negative charges, wherein the first bias voltage and the second bias voltage are polar opposites.

36. The apparatus of eliminating residual charges according to claim 35, wherein the material of the photoconductor layer includes a-Se.

37. The apparatus of eliminating residual charges according to claim 35, wherein the flat-panel x-ray detector further comprises:
a dielectric layer located between the electrode layer and the first surface.

38. The apparatus of eliminating residual charges according to claim 37, wherein the material of the dielectric layer comprises polyurethane or ethylene glycol.

39. The apparatus of eliminating residual charges according to claim 35, wherein the flat-panel x-ray detector further comprises:
a storage layer located on the second surface and comprising a plurality of pixel electrodes which is close to the second surface and configured to receive the positive charges or the negative charges.

40. The apparatus of eliminating residual charges according to claim 39, wherein the storage layer is a glass substrate.

41. The apparatus of eliminating residual charges according to claim 39, wherein the flat-panel x-ray detector further comprises:
an insulation layer located between the pixel electrodes and the second surface and entirely covering the pixel electrode.

42. The apparatus of eliminating residual charges according to claim 35, wherein the first bias voltage is a positive voltage, the second bias voltage is a negative voltage, the first electric field makes the negative charges gather at the first surface and makes the positive charges gather at the second surface, and the second electric field moves the negative charges to the second surface and moves the positive charges to the first surface.

43. The apparatus of eliminating residual charges according to claim 35, wherein the first bias voltage is a negative voltage, the second bias voltage is a positive voltage, the first electric field makes the positive charges gather at the first surface and makes the negative charges gather at the second surface, and the second electric field moves the positive charges to the second surface and moves the negative charges to the first surface.

44. The apparatus of eliminating residual charges according to claim 35, wherein the power supply is programmable and controls the polarities of the first bias voltage and the second bias voltage, output currents related to the first bias voltage and the second bias voltage, and duration of applying the first bias voltage and the second bias voltage.

45. The apparatus of eliminating residual charges according to claim 44, wherein the second bias voltage is a momentary pulse voltage.

46. The apparatus of eliminating residual charges according to claim 45, wherein a current related to the second bias voltage is smaller than a current related to the first bias voltage.

47. The apparatus of eliminating residual charges according to claim 46, wherein the power supply further generates a third bias voltage which is applied between the first surface and the second surface to produce a third electric field for moving the positive charges from the other one of the first surface and the second surface to the one of the first surface and the second surface and moving the negative charges from the one of the first surface and the second surface to the other one of the first surface and the second surface to eliminate the positive charges and the negative charges, and the second bias voltage and the third bias voltage are polar opposites.

48. The apparatus of eliminating residual charges according to claim 47, wherein the power supply alternately generates the second bias voltage and the third bias voltage.

49. The apparatus of eliminating residual charges according to claim 39, wherein the storage layer further comprises:
a plurality of switches respectively coupled between with the pixel electrodes and a ground terminal and configured to eliminate residual charges in the photoconductor layer.

50. The apparatus of eliminating residual charges according to claim 49, wherein the switch is a thin-film transistor.

51. The apparatus of eliminating residual charges according to claim 39, wherein the storage layer further comprises:
a plurality of charge storing components respectively coupled with the pixel electrodes and configured to store the positive charges or the negative charges received by the pixel electrode; and
a plurality of charge output components respectively coupled with the charge storing components and configured to acquire the stored positive charges or the stored negative charges from the charge storing component.

52. The apparatus of eliminating residual charges according to claim 51, wherein the charge storing component is a capacitor, and the charge output component is a thin-film transistor.
